(19) United States
(12) Patent Application Publication
(10) Pub. No.: US 2006/0289726 A1
(43) Pub. Date: Dec. 28, 2006

(54) Circuit arrangement

(76) Inventors: Christian Paulus, Weilheim (DE); Roland Thewes, Grobenzell (DE)

Correspondence Address: HARNESS, DICKEY & PIERCE, P.L.C., P.O.BOX 8910, RESTON, VA, 20195, US

(21) Appl. No.: 11/450,276

(22) Filed: Jun. 12, 2006

(30) Foreign Application Priority Data
Jun. 13, 2005 (DE) 10 2005 027 245.2

(51) Int. Cl. G06M 7/00

(52) U.S. Cl. 250/221

(57) ABSTRACT

A circuit arrangement is disclosed. The circuit arrangement includes a substrate, at least one sensor array arranged on and/or in the substrate, and at least one operating circuit integrated on and/or in the substrate and serving for driving the at least one sensor array. The operating circuit and the sensor array are arranged in a manner spatially separate from one another.

### PRIORITY STATEMENT

The present application hereby claims priority under 35 U.S.C. §119 on German patent application number DE 10 2005 027 245.2 filed Jun. 13, 2005, the entire contents of which is hereby incorporated herein by reference.

### Field

The invention generally relates to a circuit arrangement.

### BACKGROUND

By way of electrochemical analysis methods, substances can be determined both qualitatively and quantitatively on account of specific physical properties using the electric current. Electrochemical analysis methods in which electrode reactions play a part are of particular importance.

Together with optical methods such electrochemical analysis methods for the analytical determination of chemical and biochemical substances are characterized by a high sensitivity and also a high selectivity. Whereas, however, complicated, expensive and sensitive optical and optoelectronic apparatuses are necessary in the case of optical analysis methods, electrochemical analysis methods manage with comparatively simple electrode devices. A crucial advantage of electrochemical analysis methods is the direct presence of the measurement result as an electrical signal. The latter, after analog-digital conversion, can be processed further directly by a computer, preferably by a personal computer.

Electrochemical analysis methods are suitable for the qualitative and quantitative measurement of substance concentrations in an electrolyte solution. Every substance has an oxidation voltage and reduction voltage, respectively, that are characteristic of said substance. It is possible to distinguish between different substances on the basis of these voltages. Furthermore, the concentration of a substance present can be deduced on account of the electric current that flowed during a reaction.

In the case of voltammetry, a variable voltage is applied to the working electrode and the current flowing during an oxidation or reduction is measured. In the special case of cyclovoltammetry, a specific voltage range is repeatedly swept over in such a way that the constituents of the electrolyte are repeatedly successively oxidized and reduced.

In the case of chronoamperometry, a defined voltage is applied discontinuously to the working electrode and the current that flows is recorded over time. This measurement method permits the analysis of a specific substance by targeted oxidation or reduction of said substance. The current that flowed is a measure of the quantity of substance converted per unit time and permits conclusions to be drawn with regard to the concentration of the substance and with regard to the diffusion constant.

Chronocoulometry corresponds to chronoamperometry in terms of the electrical boundary conditions. In contrast thereto, however, the total electrical charge that flowed is recorded rather than the electric current that flowed.

In the configuration as sensors, electrode devices can be used in various electrochemical analysis methods. All that is crucial is that substances that can be evaluated electrochemically are generated during the sensor event. In the case of sensors for the detection of biomolecules, use is made of a marking method, by way of example, which provides electrochemically active substances in the case of a sensor event. Substances that can be evaluated electrochemically may be generated either directly by a sensor event or indirectly by a multistage process.

In order, moreover, to realize electrode arrays or sensor arrays which have for example 100 or more individual sensors, switching functions on the substrate which multiplex the individual sensors on to common connecting lines are advantageous. If the substrate is a semiconductor material, such as silicon, for example, the required switches may be realized by transistors. On account of the parallelization that can thereby be achieved in the tests, the analysis time is significantly shortened and it also becomes possible to carry out complex analyses.

Since an active silicon chip as a substrate, e.g. for a DNA sensor, is comparatively expensive, generally a highest possible packing density of the individual sensors in the array is striven for. Owing to the packing density of the sensors and thus of the electrodes, under certain circumstances it is not possible to realize a counterelectrode in the region of the sensor array. The counterelectrode may then be embodied as an external electrode which is arranged in the sample volume and electrically connected to the sensor chip. The driving of this electrode may be performed by a potentiostat. This procedure is disadvantageous, however, owing to comparatively long leads and the more complicated mechanical construction. If the associated disadvantages are to be avoided, the only solution offered by the prior art is to realize the counterelectrode in the periphery of the array, but this requires additional (expensive) chip area.

The sensor elements known from the prior art which are arranged in a sensor array are configured in accordance with the space requirement for accommodating the circuit elements for driving the sensor elements, as described in [1] and [2]. That is to say the size (area) of a sensor element contained in a sensor array corresponds to the space requirement of the circuit elements for said sensor element. In this case, the circuit elements usually comprise an operational amplifier and, if appropriate, an integration capacitor for coulometry. Furthermore, further circuits have to provide analog auxiliary signals and also perform digital control functions. This typically leads to sensor elements configured in square fashion and having an edge length of approximately 100-300 μm.

The associated disadvantage is, in particular, the low possible packing density of the individual sensors in a sensor array, an individual sensor or a sensor electrode in each case being arranged within a sensor element. This leads, for example in the case of an edge length of the sensor elements of 250 μm, to the fact that only 16 sensor elements can be realized per mm² of chip area. Furthermore, it is desired to arrange a large number of individual sensors or sensor elements in a sensor array, for example greater than 100 000, since a very large number of tests or analyses have to be carried out in some applications in biotechnology, which necessitates large chip areas and thus results in high chip costs or encounters the limits of realization possibilities on account of the maximum chip area available.

### SUMMARY

Consequently, at least one embodiment of the invention includes an object of realizing a highly dense arrangement of individual sensors in a sensor array using simple devices/methods.

An object may be achieved, in at least one embodiment, by way of a circuit arrangement and a monolithically integrated sensor arrangement.

Provision is made, in at least one embodiment, of a circuit arrangement including a substrate, a sensor/actuator region on and/or in the substrate, the sensor region having a plurality of sensor elements and/or a plurality of actuator elements, and also including an operating circuit region on and/or in the substrate, the operating circuit region having at least one address decoder for the addressing of the sensor elements and/or the actuator elements, respectively, and at least one evaluation circuit and/or at least one driver circuit for the sensor elements and/or the actuator elements, respectively. The operating circuit region and the sensor region are arranged in a manner spatially separate from one another, and the sensor elements and/or the actuator elements, respectively, of the sensor/actuator region are electrically coupled to the operating circuit region.

At least one embodiment of the invention can clearly be seen in the fact that, by way of the circuit arrangement and sensor arrangement according to at least one embodiment of the invention, a highly dense arrangement of individual sensors (and/or individual actuators, respectively) or sensor electrodes for electrochemical signals is possible since the circuit within a sensor element, also referred to as pixel, is restricted to the minimum required complexity. Furthermore, this is made possible by sequential operation of the sensor elements and/or actuator elements, respectively, by circuits which are arranged at the edge of the sensor/actuator array (to put it another way, in the peripheral region of the substrate around the sensor/actuator region). The architecture of the invention clearly exhibits a similarity to the architecture of semiconductor memories in which the memory cells arranged densely close to one another are read and controlled by way of peripheral sense amplifiers.

An advantage of at least one embodiment of the invention is the high packing density that can be achieved in respect of the individual sensors and/or individual actuators, respectively, that is to say the sensor elements (actuator elements) or pixels in the sensor/actuator array or in the sensor/actuator matrix. According to at least one embodiment of the invention, it is thus possible, for example in a 0.5 μm CMOS method, to realize individual sensors (individual actuators) or sensor electrodes having an edge length of less than 10 μm, which increases the packing density one hundredfold compared with conventional sensor electrodes having an edge length of 100 μm. Furthermore, however, as a result of the dense arrangement of the sensor elements, a functionalization of the sensor surface of the individual sensors or sensor electrodes by means of conventional printing methods, spotting, is possible only to a limited extent since the diameter of the liquid droplets deposited onto the sensor array or onto the sensor matrix is typically not less than 50 μm. As an alternative to functionalization by way of printing methods, it is therefore possible to use photolithographic methods or techniques, such as, for example techniques from the company Affymetrix, or else, in particular, electrochemically induced construction techniques, such as, for example, from the company Combimatrix.

In other words, according to at least one embodiment of the invention, it is possible to realize highly dense sensor arrays (sensor regions) for electrochemical signals by transferring large parts of the operating circuit of the sensor elements into the periphery of the sensor/actuator array or the sensor/actuator matrix.

An operating circuit is to be understood as, for example, a circuit arrangement for the detection and evaluation of sensor signals or else for the synthesis, immobilization or modification of the sensor-active layer situated on the individual sensors or sensor electrodes.

At least one embodiment of the invention includes a circuit arrangement including pixel circuits having low complexity and small chip area and peripheral circuit sections for the operation of the pixels or sensor elements for the detection of electrochemical signals, and/or actuator elements, for example for the functionalization of the electrode surfaces of the sensor electrode arranged within each sensor element or pixel, for the modification of the coating of the sensor electrodes or furthermore for the influencing of a sensor signal after a sensor event (stringency).

The space requirement for an individual sensor element or pixel on a chip is significantly reduced by way of the circuit arrangement. In other words, only the switching functions required for the driving of the individual sensor (and/or individual actuator, respectively) or the sensor electrodes, arranged in a sensor element, such as, for example switches for the activation or deactivation of the individual sensor (and/or individual actuator, respectively) or the sensor electrode, are arranged in a manner surrounding the individual sensors (and/or individual actuators, respectively) or the sensor electrodes. That is to say a sensor element (and/or actuator element, respectively), or pixel according to at least one embodiment of the invention has only a low functionality, such as, for example, switching functions, a preamplification, current sources, etc. Furthermore, the sensor elements (and/or actuator elements, respectively) or pixels can be controlled by means of signals which can be applied to a plurality of first lines and second lines, by means of which first lines and second lines an analog measurement signal related to a sensor signal can be applied to one or more third lines. The analog measurement signals are then measured and processed or evaluated by way of that part of the operating circuit which is arranged in a manner surrounding the sensor/actuator array. In addition, provision may also be made of an analog control of the pixel or sensor element (and/or actuator element, respectively) by peripheral circuits, for example for the synthesis of catcher molecules, as used, for example by the company Combimatrix in their products.

At least one embodiment of the invention is clearly suitable particularly for circuit architectures for monolithically integrated electrochemical (bio)sensor arrays, in particular sensors which are embodied in accordance with electrochemical principles of voltammetry or amperometry or coulometry. The size, that is to say the area requirement, of the individual sensor elements in the sensor matrix is essentially limited, in accordance with the prior art, by the area requirement of the circuits required for the operation of the sensor electrodes. Sensor elements or individual sensors that are as small as possible are desirable, however, in order to accommodate a maximum number of individual sensors on the chip area. This is achieved by means of the circuit arrangement.

In accordance with one refinement of at least one embodiment of the invention, the operating circuit region is arranged around the sensor/actuator region on and/or in the substrate.

In accordance with another refinement of at least one embodiment of the invention, the circuit arrangement is set up as a CMOS circuit arrangement.

The sensor elements may be set up as biosensor elements or as chemosensor elements. Furthermore, the sensor elements may be set up as bioactuator elements or as chemoactuator elements. Consequently, the circuit arrangement may be set up as a biosensor circuit arrangement or as a chemosensor circuit arrangement.

Furthermore, in accordance with a further refinement of at least one embodiment of the invention, the evaluation circuit is set up for the evaluation of at least one sensor event of a sensor event detected by at least one of the sensor elements.

Furthermore, the evaluation circuit may have at least one of the following electrical components:
at least one voltage source, and/or
at least one current source, and/or
at least one amplifier unit, and/or
at least one switch unit, and/or
at least one charge storage device.

These electrical components are suitable particularly for arrangement in the edge region of the circuit arrangement and for joint use for a plurality or all of the sensor elements and/or actuator elements, respectively, of the sensor/actuator region.

The addressing unit may be formed as a shift register, a latch or a memory element.

In accordance with one aspect of at least one embodiment of the invention, provision is made of a counterelectrode for setting the electrical potential of an electrolyte that is to be applied to the circuit arrangement.

Furthermore, provision may be made of a reference electrode for detecting the electrolyte potential and for driving the counterelectrode in such a way that a constant electrolyte potential is provided.

The sensor elements and/or actuator elements may be arranged in matrix form in columns and rows in the sensor/actuator region and be electrically coupled to electronic components of the operating circuit region by way of column lines or by way of row lines. In this case, the column lines may be electrically coupled to the addressing unit and the row lines may be electrically coupled to the evaluation circuit.

In accordance with one aspect of at least one embodiment of the invention, a sensor element is in each case electrically coupled to the addressing unit by means of at least one column line and to the evaluation circuit by means of at least one row line.

For example, a plurality of sensor elements and/or a plurality of actuator elements may be combined to form a group and the sensor event of each sensor element in a group of sensor elements may in each case contribute to a sensor event.

Furthermore, each sensor element and/or each actuator element individually or a group of sensor elements may be driven and evaluated.

By way of example, each sensor element and/or each actuator element or a group of sensor elements and/or actuator elements, respectively, is activated or electrically coupled to a column line by way of a switch unit.

In accordance with one refinement of at least one embodiment of the invention, a first addressing unit and a second addressing unit are provided.

The first addressing unit may be electrically coupled to the column lines and the second addressing unit may be electrically coupled to the row lines.

Furthermore, a first evaluation circuit and a second evaluation circuit may be provided.

### BRIEF DESCRIPTION OF THE DRAWINGS

Example embodiments of the invention are illustrated in the figures and are explained in more detail below.

In the figures:

FIG. 1 shows the principle of a sensor arrangement in accordance with one example embodiment of the invention,

FIG. 2 shows a sensor arrangement in accordance with a first example embodiment of the invention,

FIG. 3 shows a sensor arrangement in accordance with a second example embodiment of the invention,

FIG. 4A shows a sensor element in accordance with a first example embodiment of the invention,

FIG. 4B shows one circuitry implementation of the sensor element in accordance with the first example embodiment of the invention,

FIG. 4C shows another circuitry implementation of the sensor element in accordance with the first example embodiment of the invention,

FIG. 4D shows a sensor element in accordance with a second example embodiment of the invention,

FIG. 5 shows a sensor element in accordance with a third example embodiment of the invention,

FIG. 6 shows a sensor arrangement for coulometry in accordance with a third example embodiment of the invention,

FIG. 7A shows a sensor arrangement in accordance with a fourth example embodiment of the invention,

FIG. 7B shows a sensor arrangement in accordance with a fifth example embodiment of the invention,

FIG. 8A shows a sensor arrangement in accordance with a sixth example embodiment of the invention,

FIG. 8B shows a partial view of the sensor arrangement in accordance with an example embodiment of the invention from FIG. 8A.

### DETAILED DESCRIPTION OF THE EXAMPLE EMBODIMENTS

Hereinafter, the term “sensor” is used for describing a unit for the detection of a measurement signal and the term “actuator” is used for describing a unit for the manipulation of a sensor electrode or its coating (for example, but not limited to, by in situ synthesis of catcher molecules by electrically stimulated immobilization, or by other electrochemically induced changes in the coating before or after the sensor event, such as, for example, the stringency treatment).

Furthermore, the terms sensor pixel, sensor element, sensor electrode, sensor array or sensor matrix do not signify any restriction of the functionality of the circuit architecture and sensor arrangement according to embodiments of the invention with respect to sensor technology. It is furthermore possible, according to at least one embodiment of the invention, to provide actuator technology in such a sensor element or sensor pixel and the associated circuit architecture.

Since an electrochemical sensor/actuator is involved in accordance with these example embodiments of the invention, adequate electrochemical boundary conditions are assumed for all the example embodiments described below.

Furthermore, in addition to the sensor electrodes in the sensor matrix, at least one further electrode which functions as a counterelectrode is provided on the chip or at least in the reaction volume. According to at least one embodiment of the invention, the potential of the electrolyte situated on the sensor matrix is set by way of the counterelectrode.

According to at least one embodiment of the invention, a reference electrode in the electrochemical sense may be provided on the chip or in the external reaction volume, by which reference electrode, the electrolyte potential is measured, and which reference electrode drives the counterelectrode in such a way that a constant electrolyte potential is provided or ensured.

The counterelectrode and also the reference electrode may be arranged, for example, on the chip surface and/or monolithically integrated into the chip. The potentiostat circuit provided for the counterelectrode and the reference electrode is likewise monolithically integrated into the chip.

Furthermore, the lines for the read-out or detection of a sensor event and the lines for the functionalization of the sensor electrode surface are analog lines. This applies to all the example embodiments described below.

According to at least one embodiment of the invention, a sensor event is understood to mean oxidizable and/or reducible substances or particles which are contained in the electrolyte relative to the total quantity of substances contained in the electrolyte, this applying to all the example embodiments described below.

Furthermore, actuator technology is understood to include, for example, the generation of temporally variable voltage signals and/or currents, such as, for example, voltage jumps or voltage ramps, for the modification or functionalization of the electrode surfaces of the sensor electrode arranged within each sensor element or pixel, for the modification of the coating of the sensor electrode or for the influencing of a sensor signal after a sensor event (stringency).

In accordance with this description, furthermore, actuator operation is understood to include, for example, the driving of the sensor electrodes by way of an actuator circuit and sensor operation is understood to include the read-out of the sensor electrodes by way of an evaluation circuit.

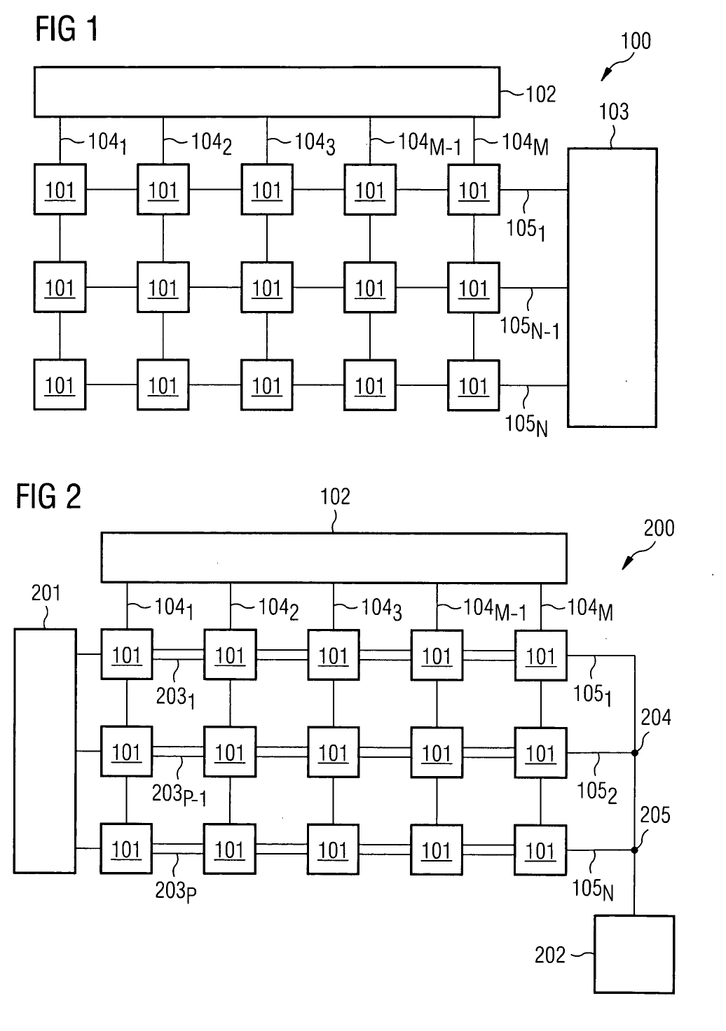

A description is given below, referring to FIG. 1, of the principle of the sensor arrangement in accordance with one example embodiment of the invention.

The sensor arrangement 100 has sensor elements 101, a first addressing unit 102, a first evaluation circuit 103, first column lines 104_{1 . . . M} and first row lines 105_{1 . . . N}. In order to simplify the illustration, only 15 sensor elements 101 are shown in FIG. 1, the sensor arrangement according to at least one embodiment of the invention having a multiplicity of sensor elements 101 arranged in columns and rows. The sensor elements 101 are electrically coupled to the first addressing unit 102 by means of the first column lines 104_{1 . . . M} and to the first evaluation circuit 103 by way of the first row lines 105_{1 . . . N}. Furthermore, the sensor elements are arranged in matrix form.

According to at least one embodiment of the invention, the sensor elements 101 which are connected to a first column line 104_{1 . . . M} or first row line 105_{1 . . . N} and are arranged in the same column of the sensor matrix are activated in each case as a group by way of the first addressing unit 102 via the first column lines 104_{1 . . . M} and are read by way of the first evaluation circuit 103 via the first row lines 105_{1 . . . N}, the information read out representing a sensor event in the form of an electrical voltage, an electric current or a quantity of electrical charge.

In other words, a complete sensor element column, or alternatively a complete sensor element row is driven or activated and subsequently read by way of the first evaluation circuit 103, the first evaluation circuit 103 having a multiplicity of electronic components, such as, for example, amplifier units, charge storage devices, switch units, voltage sources, current sources, etc., in order to detect sensor events.

FIG. 1 shows the principle of the circuit architecture and of the sensor arrangement according to at least one embodiment of the invention, the sensor elements 101 being small sensor pixels with small circuitry scope within the pixel. In other words, each sensor element 101 has a minimal switching function. That is to say that a circuit in the form of switch units for the activation and deactivation of the respective electrode in a sensor element 101 is integrated or provided within a sensor element 101.

Each sensor element 101 is addressed by way of first column lines 104_{1 . . . M} and first row lines 105_{1 . . . N} (corresponding to word and bit lines in the case of memory products), by way of a so-called function block, of the first addressing unit 102 and electrically coupled to circuit components (corresponding to sense amplifiers in the case of memory products), that is to say to the first evaluation circuit 103 for the detection of a sensor event at the edge of the sensor element matrix. For example, a complete sensor element column or a complete sensor element row may be electrically coupled to a respective operating circuit present at each column or row, respectively.

Furthermore, the line symbols, that is to say the first column lines 104_{1 . . . M} and the first row lines 105_{1 . . . N} may also be understood as bus symbols or a bus system. In other words, the sensor elements 101 may be electrically coupled to their adjacent sensor elements 101 by, in each case, a plurality of lines, that is to say first column lines 104_{1 . . . M} and first row lines 105_{1 . . . N}, respectively.

Clearly, what is achieved by transferring large parts of the operating circuit, that is to say by transferring the addressing unit and the evaluation circuit, is that sensor elements having an edge length of 10-100 μm are realized. Consequently, the density, that is to say the packing density, of sensor elements in the sensor arrangement, according to at least one embodiment of the invention is increased by a factor of 100 in comparison with the prior art.

A description is given below, referring to FIG. 2 of a sensor arrangement in accordance with a second example embodiment of the invention.

The sensor arrangement 200 has the sensor elements 101, the first addressing unit 102, the first column lines 104_{1 . . . N}, the first row lines 105_{1 . . . M}, a second addressing unit 201, a second evaluation circuit 202, second row lines 203_{1 . . . p}, a first node 204 and a second node 205. The first addressing unit 102 is electrically coupled to the first column lines 104_{1 . . . N} and the second addressing unit 201 is electrically coupled to the row lines 105_{1 . . . M}. The sensor elements 101, in each row, are electrically coupled to the adjacent sensor elements 101 in the same row by way of second row lines 203_{1 . . . p}. Furthermore, the sensor element rows are electrically coupled to one another by way of the row lines 105_{1 . . . M} and by way of the nodes 204, 205. The second evaluation circuit 202 is electrically coupled to the second node 205.

In accordance with the first example embodiment of the invention, the second row lines 203_{1 . . . p} serve as further analog lines for the selection of individual sensor elements 101 within the sensor arrangement or the sensor matrix, so that only a few sensor elements 101 are simultaneously coupled to peripheral circuit sections, that is to say the operating circuit or the second evaluation circuit 202, or else only a single sensor element 101 is electrically coupled to the evaluation circuit 202.

In other words, it is thus possible for individual sensor elements 101 to be driven or read in a targeted manner by way of a second row line 203_{1 . . . p} in order to detect a sensor event at the sensor element 101 or to register it by way of the second evaluation circuit 202.

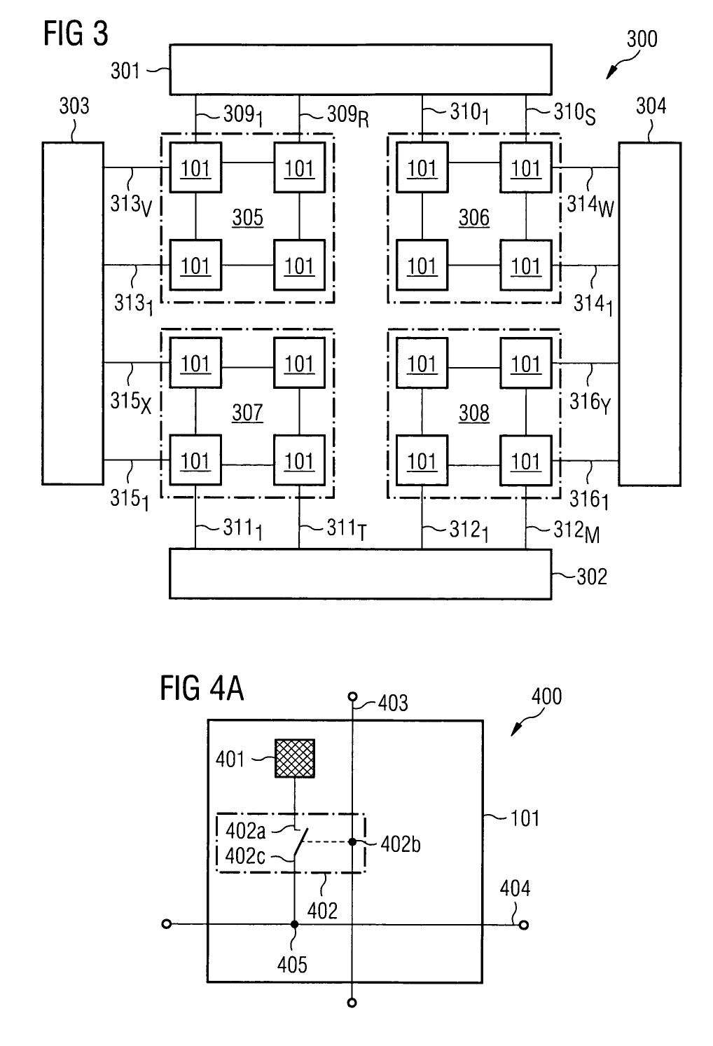

A description is given below, referring to FIG. 3 of a sensor arrangement in accordance with a second example embodiment of the invention.

The sensor arrangement 300 has the sensor elements 101, a third addressing unit 301, a fourth addressing unit 302, a third evaluation circuit 303, a fourth evaluation circuit 304, a first sensor element block 305, a second sensor element block 306, a third sensor element block 307, a fourth sensor element block 308, second column lines 309_{1 . . . R}. third column lines 310_{1 . . . S}, fourth column lines 311_{1 . . . T}, fifth column lines 312_{1 . . . U}, third row lines 313_{1 . . . R}, fourth row lines 314_{1 . . . S}, fifth row lines 315_{1 . . . T} and sixth row lines 316_{1 . . . U}, the first sensor element block 305 having four sensor elements 101, the second sensor element block 306 having four sensor elements 101, the third sensor element block 307 having four sensor elements 101 and the fourth sensor element block 308 having four sensor elements 101. In order to simplify the illustration of FIG. 3, only four sensor elements 101 are shown per sensor element block 305, 306, 307 and 308. According to at least one embodiment of the invention, a multiplicity of sensor elements 101 may be arranged in each sensor element block 305, 306, 307 and 308.

Furthermore, the sensor elements 101 in each of the sensor element blocks 305, 306, 307 and 308 may be, for example, arranged in matrix form, that is to say in columns and rows. The sensor elements 101 of the first sensor element block 305 are electrically coupled to the third addressing unit 301 by way of the second column lines 309_{1 . . . R} and to the third evaluation circuit 303 by means of the third row lines 313_{1 . . . V}. The sensor elements 101 of the second sensor element block 306 are electrically coupled to the third addressing unit 301 by way of the third column lines 310_{1 . . . S} and to the fourth evaluation circuit 304 by way of the fourth row lines 314_{1 . . . W}. The sensor elements 101 of the third sensor element block 307 are electrically coupled to the fourth addressing unit 302 by way of the fourth column lines 311_{1 . . . T} and to the third evaluation circuit 303 by way of the fifth row lines 315_{1 . . . X}. The sensor elements 101 of the fourth sensor element block 308 are electrically coupled to the fourth addressing unit 302 by way of the fifth column lines 312_{1 . . . U} and to the fourth evaluation circuit 304 by way of the sixth row lines 316_{1 . . . Y}. Furthermore, the sensor element blocks 305, 306, 307, 308 are not directly electrically coupled to one another, so that four sensor elements 101 in a sensor element block 305, 306, 307, 308 always contribute to a sensor event.

As in the case of memory products, it is possible, in accordance with the second example embodiment of the invention, to make use of the fact that the sensor arrangement may have operating circuits, that is to say addressing units and evaluation circuits on all four sides of the sensor matrix.

In other words, it is therefore possible to divide the sensor matrix in two or more sensor element blocks or parts that can be operated independently of one another. This increases the processing speed of the sensor data and/or actuator signals. That is to say that by virtue of a parallelization of the detection of sensor events, a multiplicity of sensor data or sensor events can be processed simultaneously by means of the evaluation circuits.

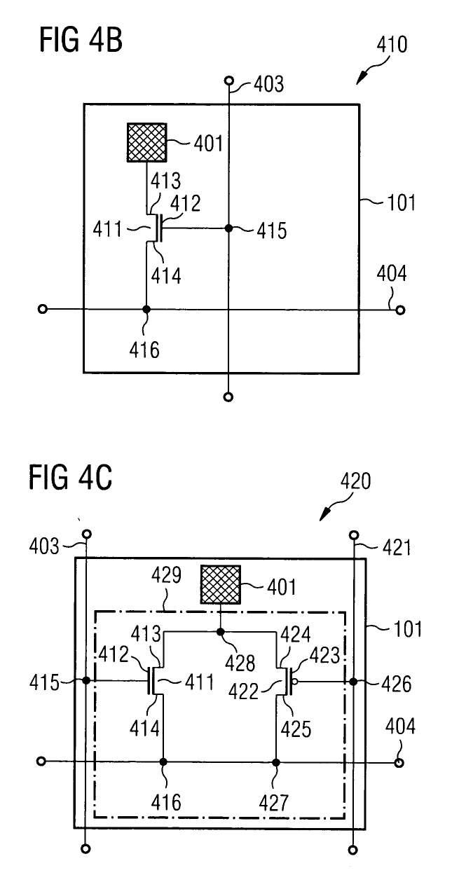

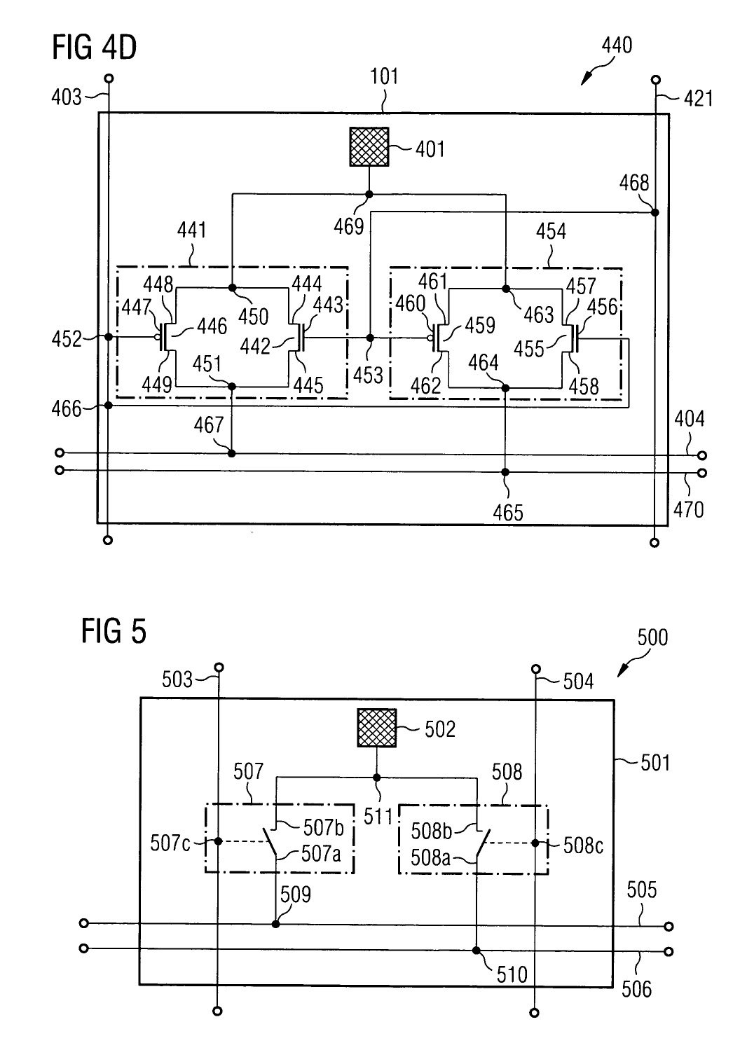

A description is given below, referring to FIG. 4A, of a sensor element in accordance with a first embodiment of the invention.

The sensor element 101 of the arrangement 400 has a sensor electrode 401, a first switch unit 402 having a first terminal 402a, a second terminal 402b and a third terminal 402c, a first column line 403, a first row line 404 and a first node 405. The sensor electrode is electrically coupled to the first terminal 402a of the first switch unit 402. The first column line 403 is electrically coupled to the second terminal 402b of the first switch unit 402. The first row line 404 is electrically coupled to the third terminal 402c of the first switch unit 402 by means of the first node 405.

According to at least one embodiment of the invention, the first switch unit 402 can be controlled by means of signals which are transmitted by way of the first column line 403. That is to say the first switch unit 402 is controlled by an addressing unit (not shown in FIG. 4A), such as, for example, the addressing unit 102. As a result, the first switch unit 402 can be controlled in such a way that the sensor electrode 401 is or is not electrically coupled to the first row line 404. If the sensor electrode 401 is electrically coupled to the first row line 404 by way of the first switch unit 402, then it is possible, by way of an evaluation circuit such as, for example, the evaluation circuit 103, connected to the first row line 404, for a sensor event to be detected and evaluated or for the surface of the sensor electrode to be modified or influenced in a desired manner by way of actuator technology of the evaluation circuit.

In accordance with the circuit architecture shown in FIG. 4A, it is possible for each sensor electrode to be driven individually, without other adjacent sensor electrodes having to be activated for this purpose, since each sensor element 101 or sensor pixel only has a switching function in the form of the first switch unit 402, which is controlled by way of the first column line 403, the first switch unit 402 electrically coupling the sensor electrode 401 to an analog line, the first row line 404. The first row line 404 is electrically coupled at the edge of the sensor matrix to at least one part of the operating circuit, that is to say to an evaluation circuit, it being possible for the evaluation circuit to be set up in such a way that it drives the sensor electrode 401 in a suitable manner or the sensor electrode 401 fulfils the functionality of a sensor.

In other words, the evaluation circuit, such as for example, the evaluation circuit 103, is set up in such a way that the sensor electrode 401 functions as an actuator. That is to say that suitable currents or voltages are applied to the sensor electrode 401 in order thus to induce an electrochemical conversion.

In an operating method, the column line of a column of sensor elements is set to a “high” potential, as a result of which the sensor electrode of all the sensor elements of the column is electrically coupled to the respective analog row line. By way of the evaluation circuit at the edge of the sensor matrix, it is then possible to apply suitable voltages or currents to the respective sensor electrode in order thereby to induce an electrochemical conversion, the sensor electrode thus functioning as an actuator. Furthermore, it is also possible, by way of the peripheral operating circuit, to carry out an electrochemical detection and evaluation of a sensor event that has taken place at the respective sensor electrode, for example by way of a coulometric method, the sensor electrode thus functioning as a sensor.

A description is given below, referring to FIG. 4B, of a circuitry implementation of the sensor element in accordance with the first embodiment of the invention.

The sensor element 401 of the arrangement 410 has the sensor electrode 401, the first column line 403, the first row line 404, a first transistor 411 having a gate 412, a first source/drain terminal 413, a second source/drain terminal 414, a first node 415 and a second node 416, the gate 412 of the first transistor 411 being electrically coupled to the first column line 403 by way of the first node 415, the first source/drain terminal 413 being electrically coupled to the sensor electrode 401 and the second source/drain terminal 414 being electrically coupled to the first row line 404 by way of the second node 416.

As shown in accordance with FIG. 4B, the first switch unit 402 from FIG. 4A is realized by a first transistor 411, it being possible for the first transistor 411 to be embodied as an NMOS transistor or PMOS transistor. Furthermore, provision is also made for providing a complete transmission gate, comprising an NMOS transistor and a PMOS transistor, instead of the first transistor 411.

A description is given below, referring to FIG. 4C, of another circuitry implementation of the sensor element in accordance with the first embodiment of the invention.

The sensor element 401 of the arrangement 420 has the sensor electrode 401, the first column line 403, the first row line 404, the first transistor 411 having the gate 412, the first source/drain terminal 413, the second source/drain terminal 414, the first node 415, the second node 416, a second column line 421, a second transistor 422 having a gate 423, a first source/drain terminal 424, a second source/drain terminal 425, a third node 426, a fourth node 427 and a fifth node 428, the first source/drain terminal 413 of the first transistor 411, the first source/drain terminal 424 of the second transistor 422 and the sensor electrode 401 being electrically coupled to the fifth node 428. The second source/drain terminal 414 of the first transistor 411 is electrically coupled to the first row line 404 by means of the second node 416. The second source/drain terminal 425 of the second transistor 422 is electrically coupled to the first row line 404 by means of the fourth node 427. The gate 412 of the first transistor 411 is electrically coupled to the first column line 403 by means of the first node 415. The gate 423 of the second transistor 422 is electrically coupled to the second column line 421 by means of the third node 426.

Furthermore, the first column line 403 and the second column line 421 are arranged parallel to one another and perpendicular to the first row line 404. The sensor electrode 401, the first transistor 411 and the second transistor 422 are arranged between the first column line 403 and the second column line 421.

The first transistor 411 is furthermore an NMOS transistor and the second transistor 422 is a PMOS transistor, so that the first transistor 411 and the second transistor 422 form a complete first transmission gate 429.

In accordance with this embodiment of the sensor element 101, the first transistor 411 and the second transistor 422 must be driven by way of two complementary signals from an addressing unit, for example, the addressing unit 102 (not shown) or by way of a local inverter circuit (not shown), that is to say inverter circuit integrated in the sensor element 101, which inverter circuit generates the complementary signal locally, the signal on the second column line 421 always having the complementary signal with respect to the signal on the first column line 403.

In accordance with this example embodiment, the abovementioned first transmission gate 429 having the first transistor 411 and the second transistor 422 serves as an analog switch by which positive and negative signal voltages are switched, the signal voltages having an opposite polarity. In other words, the signal on the second column line 421 is at a “low level” if the signal on the first column line 403 is at a “high level”, and vice versa, a “high level” corresponding to a positive signal voltage and a “low level” corresponding to a negative signal voltage.

Consequently, the first transistor 411 and the second transistor 422 are in a switched-on state, if a positive signal voltage is present on the first column line 403 and a negative signal voltage is present on the second column line 421, and in a switched-off state if a negative signal voltage is present on the first column line 403 and a positive signal voltage is present on the second column line 421. Consequently, it is possible in the case of switched-on transistors to switch positive and negative signal voltages. That is to say that after a sensor event at the sensor electrode either a positive or negative potential is present or that in the case of an actuator a positive or negative signal voltage can be applied to the sensor electrode; in this context, the positive and also the negative potential are to be understood as a charge shift or a potential difference with respect to the electrolyte situated on the sensor matrix or sensor electrode.

Since the sensor arrangement and also the operating circuit are embodied using CMOS technology and since CMOS circuits have a low current consumption and a large operating voltage range, it is possible to use the sensor arrangement according to at least one embodiment of the invention as field application, that is to say as a portable, battery operated measurement and analysis device.

A description is given below, referring to FIG. 4D of a sensor element in accordance with a second embodiment of the invention.

The sensor element 101 of the arrangement 440 has the sensor electrode 401, the first column line 403, the first row line 404, the first node 415, the second node 416, the third node 426, the fifth node 428, a first transmission gate 441, the first transmission gate 441 having a first transistor 442, having a gate 443, a first source/drain terminal 444, a second source/drain terminal 445, a second transistor 446 having a gate 447, a first source/drain terminal 448, a second source/drain terminal 449, a first node 450 and a second node 451, a third node 452, a fourth node 453, a second transmission gate 454, the second transmission gate 454 having a first transistor 455 having a gate 456, a first source/drain terminal 457, a second source/drain terminal 458, a second transistor 459 having a gate 460, a first source/drain terminal 461, a second source/drain terminal 462, a first node 463 and a second node 464, a fifth node 465, a sixth node 466, a seventh node 467, an eighth node 468, a ninth node 469 and a second row line 470.

The switching structure within the sensor element 401 is described below referring to the first transmission gate 441. The first source/drain terminal 444 of the first transistor 442 and the first source/drain terminal 448 of the second transistor 446 are electrically coupled to one another by way of the first node 450, and the second source/drain terminal 445 of the first transistor 442 and the second source/drain terminal 449 of the second transistor 446 are electrically coupled to one another by means of the second node 451. The first transistor 442 is thereby connected in parallel with the second transistor 446 in a parallel circuit. Furthermore, the first transistor 442 is an NMOS transistor and the second transistor 446 is a PMOS transistor.

The first node 450 is electrically coupled to the sensor electrode 401 by way of the ninth node 469, as a result of which the parallel circuit comprising the first transistor 442 and the second transistor 446 is electrically coupled to the sensor electrode 401 by way of the first node 450 and the ninth node 469. Furthermore, the gate 447 of the second transistor 446 is electrically coupled to the first column line 403 by way of the third node 452 and the gate 443 of the first transistor 422 is electrically coupled to the second column line 421 by way of the fourth node 453. The second node 451 is electrically coupled to the first row line 404 by way of the seventh node 467, as a result of which the parallel circuit including the first transistor 442 and the second transistor 446 is electrically coupled to the first row line 403 by way of the second node 451 and by way of the seventh node 467.

The switching structure within the sensor element 101 is described below referring to the second transmission gate 454. The first source/drain terminal 457 of the first transistor 455 and the first source/drain terminal 461 of the second transistor 459 are electrically coupled to one another by way of the first node 463 and the second source/drain terminal 458 of the first transistor 455 and the second source/drain terminal 462 of the second transistor 459 are electrically coupled to one another by way of the second node 464. The first transistor 455 is thereby connected in parallel with the second transistor 459 in a parallel circuit. Furthermore, the first transistor 455 is an NMOS transistor and the second transistor 459 is a PMOS transistor.

The first node 463 is electrically coupled to the sensor electrode 401 by way of the ninth node 469, as a result of which the parallel circuit comprising the first transistor 455 and the second transistor 459 is electrically coupled to the sensor electrode 401 by way of the first node 463 and the ninth node 469. Furthermore, the gate 460 of the second transistor 459 is electrically coupled to the second column line 421 by way of the fourth node 453 and the gate 456 of the first transistor 455 is electrically coupled to the first column line 403 by way of the sixth node 466. The second node 464 is electrically coupled to the second row line 470 by way of the fifth node 465, as a result of which the parallel circuit comprising the first transistor 455 and the second transistor 459 is electrically coupled to the second row line 470 by way of the second node 464 and by way of the fifth node 465.

In accordance with this example embodiment of the sensor element 401, the first transmission gate 441 and the second transmission gate 454 serve as switch units or as changeover switches in order to electrically couple the sensor electrode 401 to the respective row line, that is to say either to the first row line 404 or to the second row line 470. For proper operation of the changeover switch, it is necessary to drive the transistors 442, 446, 455 and 459 by way of complementary signals. In other words, one of the two transmission gates 441, 454 is always switched off.

If a low level is present on the first column line 403 and a high level is present on the second column line 421, then the first transmission gate 441 is activated or switched on since the second transistor 446 is in a switched-on state as a result of the low level on the first column line 403 and the first transistor 442 of the first transmission gate 441 is in a switched-on state as a result of a high level on the second column line 421, the sensor electrode 401 thereby being electrically coupled to the first row line 404. If a high level is present on the first column line 403 and a low level is present on the second column line 421, the situation is exactly the opposite, and the second transmission gate 454 is switched on, as a result of which the sensor electrode 401 is electrically coupled to the second row line 470.

In accordance with the above-described switching function of the sensor element 401 in accordance with this example embodiment, it is possible to use the sensor electrode for example as a sensor or as an actuator.

Furthermore, the sensor arrangement causes a selective read-out of the sensor element columns or sensor element rows or of individual sensor elements of the sensor matrix. Since only a very short time duration, typically 0.1-10 ms is required for the “writing” (actuator) or “reading” (sensor) of a sensor element or a sensor electrode, even very large sensor arrays can be completely read sufficiently rapidly. The reason for this resides in the simple or minimal switching function of each sensor element. Furthermore, the sensor electrodes of the non-addressed sensor elements, during a sequential read-out operation, are either switched in current-free fashion, that is to say that their potential results from the potential of the electrolyte, or a specific standby signal, e.g. standby potential or standby current, is applied to the electrode.

A description is given below referring to FIG. 5, of a sensor element in accordance with a third example embodiment of the invention.

The sensor element 501 of the arrangement 500 has a sensor electrode 502, a first column line 503, a second column line 504, a first row line 505, a second row line 506, a first switch unit 507, a second switch unit 508, a first node 509, a second node 510 and a third node 511, the first switch unit 507 having a first terminal 507a, a second terminal 507b and a third terminal 507c, and the second switch unit 508 having a first terminal 508a, a second terminal 508b, and a third terminal 508c.

The first terminal 507a of the first switch unit 507 is electrically coupled to the first row line 505, by means of the first node 509, the second terminal 507b is electrically coupled to the sensor electrode 501 by way of the third node 511, and the third terminal 507c is electrically coupled to the first column line 503. The first terminal 508a of the first switch unit 508 is electrically coupled to the second row line 506 by way of the second node 510, the second terminal 508b is electrically coupled to the sensor electrode 501 by way of the third node 511, and the third terminal 508c is electrically coupled to the second column line 504.

Furthermore, either the first switch unit 507 or the second switch unit 508 is driven, so that the sensor electrode 502 is electrically coupled either to the first row line 505 or to the second row line 506. That is to say that the sensor electrode 502 is electrically coupled to the first row line 505 if the first switch unit 507 is switched on, and is electrically coupled to the second row line 506 if the second switch unit 508 is switched on, it being presupposed that the switch units 507, 508 are not both switched on. If provision is made for not driving the sensor electrode 502, then the first switch unit 507 and the second switch unit 508 are switched off or one of the two switch units 507, 508 is switched on in order to put the sensor electrode 502 at a defined potential if no electrochemical conversion is intended to take place at this sensor electrode.

In accordance with the switching function of the sensor element 501, it is possible, in particular, to use the sensor electrode 502 both as a sensor and as an actuator since the sensor electrode 502 can optionally be electrically coupled to the first row line 505 or to the second row line 506. Consequently, it is possible, as explained, depending on the addressing of the sensor electrodes, for the sensor electrodes optionally to be electrically coupled to a peripheral sensor circuit or to a peripheral actuator circuit of the operating circuit which is arranged at the edge of the sensor matrix.

The sensor electrodes are electrically coupled to an actuator circuit, in particular, when they are intended to be functionalized by way of voltages and/or currents. In other words, the surface of the sensor electrodes can be modified by way of suitable voltages and/or currents according to the sensor event to be detected, for example for the purpose of immobilizing DNA catcher molecules on the sensor electrode surface.

Furthermore, the sensor electrodes of inactive or non-driven or non-activated sensor elements can be put at a defined potential, or carry a defined current, so that their sensor surface is not influenced, or else is influenced in a desirable but controlled manner by conversions at adjacent sensor electrodes.

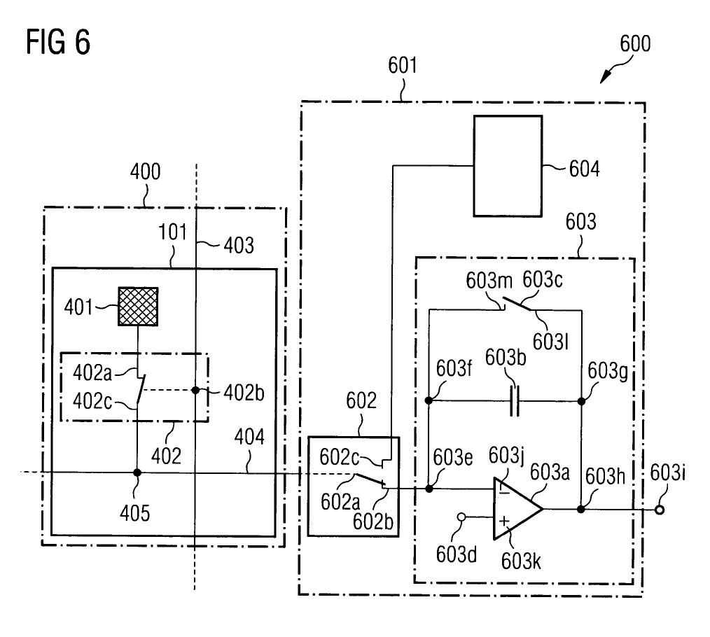

A description is given below, referring to FIG. 6, of a sensor arrangement for coulometry in accordance with the third example embodiment of the invention.

FIG. 6 shows at least part of the sensor arrangement according to at least one embodiment of the invention and serves the purpose of elucidation, part of the operating circuit surrounding the sensor matrix which has a circuit for coulometric evaluation of the sensor electrodes being shown. Furthermore, a multiplicity of sensor elements 101 may be arranged, for example, adjacent in columns and rows and each sensor element row is preferably electrically coupled to an evaluation circuit.

The sensor arrangement 600 has the arrangement 400, which will not be explained in detail at this juncture, and a circuit 601. The circuit 601 has a switch unit 602 having a first terminal 602a, a second terminal 602b, a third terminal 602c, an evaluation circuit 603, an actuator circuit 604 and a terminal 605. The evaluation circuit 603 has an amplifier unit 603a, a charge storage device 603b, a switch unit 603c, a first terminal 603d, a second terminal 603e, a first node 603f, a second node 603g, a third node 603h, and a third terminal 603i, the switch unit 603c constituting a reset transistor in a representative manner. The amplifier unit 603a has a negative terminal 603j and a positive terminal 603k, the negative terminal 603j being electrically coupled to the second terminal 603e and the positive terminal 603k being electrically coupled to the first terminal 603d.

The output of the amplifier unit 603a is electrically coupled to the third node 603h, as a result of which the amplifier unit 603a is arranged between the second terminal 603e and the third node 603h. Furthermore, the second terminal 603e is electrically coupled to the first node 603f and the third node 603 is electrically coupled to the second node 603g. The charge storage device 603b, which is preferably a capacitor, is arranged in parallel with the amplifier unit 603a and is electrically coupled to the first node 603f and the second node 603g. The switch unit 603c has a first terminal 603l and a second terminal 603m, the first terminal 603l being electrically coupled to the second node 603g and the second terminal 603m being electrically coupled to the first node 603f, and the switch unit 603c thus being arranged in parallel with the charge storage device 603b.

The function of the arrangement 600 according to at least one embodiment of the invention is described below.

The example embodiment of FIG. 6 according to the invention shows a circuit architecture for coulometry that is to say for the detection of quantities of charge from electrochemical conversions. The sensor element 101 of the arrangement 400 illustrated on the left of FIG. 6 is selected or activated by way of the switch unit 402, which has previously been switched by way of an activation signal via the column line 403, as a result of which the sensor electrode 401 is electrically coupled to the column line 404. The evaluation circuit 603 or integrator circuit illustrated in the circuit 601 stores the quantity of charge which occurs or has occurred as a result of a voltage jump at the sensor electrode 401 on account of a possible electrochemical conversion or a sensor event.

Furthermore, the evaluation circuit 603 forms an integrator for storing charge. The evaluation circuit 603 is electrically coupled to the second terminal 602b of the switch unit 602 by way of the second terminal 603e. The actuator circuit 604 is electrically coupled to the third terminal 602c of the switch unit 602 and furthermore has voltage sources, current sources, etc.

The switch unit 602 is electrically coupled, by way of its first terminal 602a, to the sensor element 101 of the arrangement 400 via the row line 404, and the sensor electrode 401 is consequently electrically coupled to the circuit 601.

The method for the sequential read-out of the columns of the sensor array may be carried out as follows. The integrator of the evaluation circuit 601 arranged at the row edge of the sensor array is reset by way of the charge storage device 603b or the capacitor being discharged by way of the reset transistor 603c, for which purpose the first terminal 603l is electrically coupled to the second terminal 603m of the switch unit 603c. The sensor element 101 is selected or activated by way of the column line 403. A voltage jump is subsequently carried out or initialized at the sensor electrode 401 by way of the voltage present at the first terminal 603d of the amplifier unit 603a being abruptly increased or reduced depending on the measuring method. The charge that flows in total in the case of this voltage jump is stored by way of the charge storage device 603b and can be read out after deactivation of the sensor element 101 as output voltage at the third terminal 603i. The next sensor element 101 or the next sensor electrode 401 can be measured after renewed resetting of the charge storage device 603b.

In practice, it is advantageous for the voltage present at the first terminal 603d always to be held at the target potential of the voltage jump at the sensor electrode 401, and for the sensor electrodes 401 to be raised through activation by way of the respective column line from their initial potential, for example, the electrolyte potential or the potential of a second row line to the target potential. As a result of this, the potential of the row line, which may be very long and beset with a large parasitic capacitance, remains constant and the quantity of charge measured by way of the evaluation circuits corresponds to the greatest possible extent to the electrochemically converted quantity of charge at the sensor electrodes of a sensor element column, that is to say to the actual measurement signal. If the quantities of charge of a sensor element column are detected according to the invention, said sensor element column can be deselected or deactivated, the charge storage device 603b can be reset and the next directly adjacent or not directly adjacent sensor element column can be selected or activated.

In accordance with this method, it is possible for the sensor matrix to be progressively read completely in a comparatively short time duration.

Furthermore, a switch unit, such as the switch unit 602, for example, is provided or arranged in the periphery of the sensor matrix, that is to say in the operating circuit, which switch unit enables a changeover between sensor operation and actuator operation of the sensor electrodes. By way of the switch unit 602 it is possible to realize both actuator operation and sensor operation with only a single row line, such as the row line 404, for example, and only one switching function within the sensor element 101, the first terminal 602a being electrically coupled to the second terminal 602b of the switch unit 602 for sensor operation and the first terminal 602a being electrically coupled to the third terminal 603c of the switch unit 602 for actuator operation.

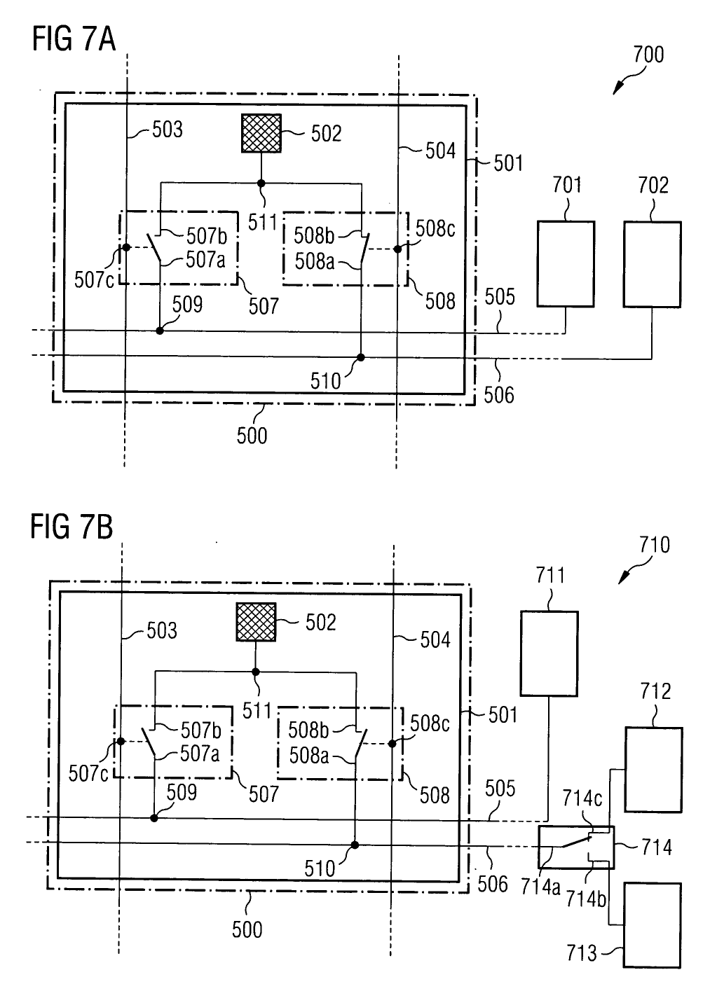

A description is given below, referring to FIG. 7A of a sensor arrangement in accordance with a fourth example embodiment of the invention.

The arrangement 700 has the sensor element 501 in accordance with FIG. 5, which will therefore not be explained any further here, it being the case that a multiplicity of arrangements 700 arranged in columns and rows are provided and the example embodiment in accordance with FIG. 7A is therefore not to be regarded as a restriction of the invention. Furthermore, the arrangement 700 has an evaluation circuit 701, which is set up for detecting sensor events in the form of electrochemical conversions, and an actuator circuit 702 which is set up for modifying the sensor electrode 502 electrically coupled thereto.

The evaluation circuit 701 is electrically coupled to the first row line 505 and the actuator circuit 702 is electrically coupled to the second row line 506.

In accordance with this example embodiment, the sensor electrode 502 can be electrically coupled either to the evaluation circuit 701 or to the actuator circuit in order, as already described, to evaluate the sensor electrode 502 by way of the evaluation circuit 701 or to functionalize the sensor electrode surface in a suitable manner by way of the actuator circuit 702, the sensor element 501 having only two switch units, the switch unit 507, 508, for electrically coupling the sensor electrode 502 to two analog row lines, the row lines 505, 506. Furthermore, the evaluation circuit 701 and the actuator circuit 702 are arranged at the edge of the sensor matrix, so that only a minimal part of the circuit arrangement according to the invention is contained in the sensor matrix, as a result of which the size or area of each sensor element 501 is reduced.

The evaluation circuit 701 serves for detecting a sensor event, that is to say, in particular, for measuring and/or amplifying and/or processing an electrical voltage, an electric current or a quantity of charge. The evaluation circuit 701 may be an integrator circuit, for example as illustrated in FIG. 6.

The actuator circuit 702 serves for functionalizing, modifying or influencing in some other way the sensor electrode surface of the sensor electrode 502. For this purpose, the actuator circuit 702 can provide the sensor electrode 502 with a suitable voltage, a suitable current and/or a quantitative charge, this leading to the desired electrochemical reaction at the sensor electrode surface.

The sensor electrode 502 is electrically coupled to the respective analog row line by means of the first column line 503 or by way of the second column line 504. That is to say the sensor electrode 502 is electrically coupled to the first row line 505 if the first switch unit 507 is switched on by way of a signal via the first column line 503, and to the second row line 506 if the second switch unit 508 is switched on by way of a signal via the second column line 504.

Furthermore, the sensor electrode 502 can be switched in potential-free fashion by the first switch unit 507 and the second switch unit 508 being deactivated.

In accordance with this example embodiment, it is furthermore possible for complete sensor element columns to be read or functionalized. For the read-out or functionalization of the sensor electrodes of a sensor element column, the respective sensor electrode of the activated sensor element column which is intended to be read or functionalized is either electrically coupled to one of the analog row lines, while the sensor elements of the remaining sensor element columns are put at a defined potential.

A description is given below, referring to FIG. 7B of a sensor arrangement in accordance with a fifth example embodiment of the invention.

The arrangement 710 of FIG. 7B has the sensor element 501 in accordance with FIG. 5, which will therefore not be explained any further here, it being the case that a multiplicity of arrangements 710 arranged in columns and rows are provided and the example embodiment in accordance with FIG. 7B is therefore not to be regarded as a restriction of embodiments of the invention. Furthermore, the arrangement 710 has a standby circuit 711, an actuator circuit 712, an evaluation circuit 713 and a third switch unit 714 having a first terminal 714a, a second terminal 714b and a third terminal 714c. The standby circuit 711 is electrically coupled to the first row line 505 and the switch unit 714 is electrically coupled to the second row line 506. Consequently, either the actuator circuit 712 or the evaluation circuit 713 is electrically coupled to the sensor electrode 502 provided that the second switch unit 508 is switched on.

By way of the standby circuit 711, a defined potential can be applied to the sensor electrode 502 provided that the first switch unit 507 is switched on, the switching on of the first switch unit 507 being performed by way of a suitable signal via the first column line 503. If the second switch unit 508 has been switched on, then subsequently either the actuator circuit 712 or the evaluation circuit 713 can be electrically coupled to the sensor electrode 502 by way of the third switch unit 714, the first terminal 714a being electrically coupled to the third terminal 714c for actuator operation and the first terminal 714a being electrically coupled to the second terminal 714b of the third switch unit 714 for sensor operation.

One advantage in accordance with the example embodiments of FIG. 7A and FIG. 7B with two or more analog row lines is that during the progressive programming of the sensor matrix (actuator operation) or during the progressive read-out (sensor operation) the respective inactive sensor element columns or sensor element rows do not have to be switched in potential-free fashion, but rather can be switched to a defined potential or a defined current. In this case, the signal is selected in such a way that no undesirable or uncontrolled electrochemical conversions take place at the respective inactive sensor electrodes.

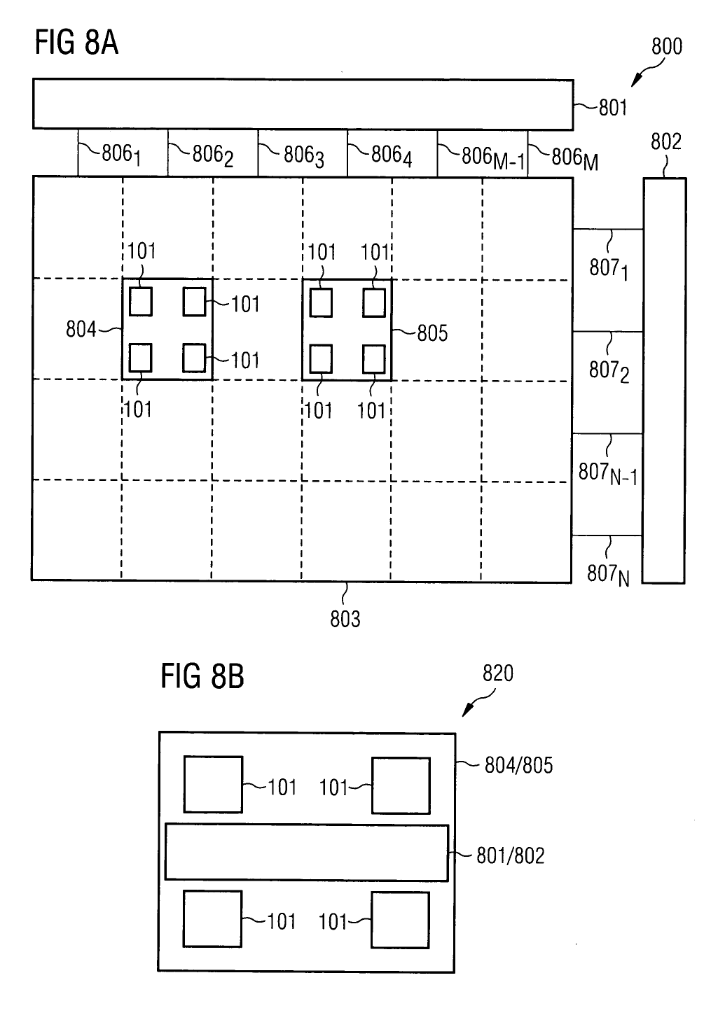

A description is given below, referring to FIG. 8A, of a sensor arrangement in accordance with a sixth example embodiment of the invention.

The arrangement 800 has sensor elements 101, an addressing unit 801, an evaluation circuit 802, a sensor matrix 803 having a first sensor element group 804 and a second sensor element group 805, column lines 806_{1 . . . M} and row lines 807_{1 . . . N}.

Furthermore, a multiplicity of sensor element groups 804, 805 may be arranged within the sensor matrix 803, the sensor element groups having at least four sensor elements 101.

In accordance with this example embodiment, whole or parts of sensor element columns or sensor element rows are not connected to peripheral sensor or actuator circuits, rather the sensor elements 101 of the sensor matrix 803 are organized into small groups including a plurality of sensor element columns or sensor element rows and these partial groups of the sensor matrix 803 share peripheral operating circuits, such as, for example, addressing units and evaluation circuits. In this case, the grouped sensor elements may originate from adjacent sensor element columns or sensor element rows or furthermore be distributed, for example regularly over the sensor matrix 803.

The peripheral operating circuits of sensor elements grouped in this way may be set up for specific analysis purposes and relate the signals or the sensor events of the sensor elements to one another in respect of this. This is of interest in SNP detection (single nucleotide polymorphism), for example, in which the actual sensor event is determined from the signals or the sensor events of at least four sensor elements. The peripheral operating circuits of the sensor element group may be embodied in such a way that the specific application is taken into account both in actuator operation and in sensor operation.

A description is given below, referring to FIG. 8B of a partial view of the sensor arrangement from FIG. 8A.

The arrangement 820 shows the sensor element group 804, 805 having four sensor elements 101, the addressing unit 801 and the evaluation circuit 802, the addressing unit 801 and the evaluation circuit 802 being shown symbolically between the four sensor elements 101 in order to indicate that the four sensor elements 101 arranged to form the sensor element group 804/805 share parts of the operating circuit arranged at the edge of the sensor matrix 803.

As already explained in accordance with FIG. 8A, a plurality of sensor elements 101 from adjacent sensor element columns and sensor element rows may in each case be combined in the sensor element groups 804, 805. Furthermore, the sensor element groups 804, 805 may also be combined from non-adjacent sensor element columns and sensor element rows to form groups, the sensor elements 101, for example, being distributed regularly within the sensor matrix 803 for this purpose. In other words, by way of example, the four sensor elements of the sensor element group 804, 805 may be combined from four different columns, four different rows, or from two arbitrary columns or two arbitrary rows, to form a group.

The following publications are cited in this document:
[1] M. Schienle et al., “A Fully Electronic DNA Sensor with 128 Positions and In-Pixel A/D Conversion”, Proc. International Solid State Circuits Conference (ISSCC) 2004;
[2] C. Paulus et al., “A Fully Integrated CMOS Sensor System for Chronocoulometry”, Proc. IEEE Sensors Conference 2003, p. 1329-1332.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A circuit arrangement, comprising:
a substrate;
a sensor/actuator region, at least one of on and in the substrate, the sensor/actuator region including at least one of a plurality of sensor elements and a plurality of actuator elements;
an operating circuit region at least one of on and in the substrate, the operating circuit region having at least one address decoder for the addressing of at least one of the sensor elements and actuator elements, respectively, and at least one of at least one evaluation circuit and at least one driver circuit for at least one of the sensor elements and actuator elements, respectively,
the operating circuit region and the sensor/actuator region being arranged in a manner spatially separate from one another, and
at least one of the sensor elements and the actuator elements, respectively, of the sensor/actuator region, being electrically coupled to the operating circuit region.

2. The circuit arrangement as claimed in claim 1, wherein the operating circuit region is arranged around at least one of the sensor/actuator region and in the substrate.

3. The circuit arrangement as claimed in claim 1, wherein the circuit arrangement is set up as a CMOS circuit arrangement.

4. The circuit arrangement as claimed in claim 1, wherein at least one of the sensor elements and the actuator elements are set up as at least one of biosensor elements and chemosensor elements.

5. The circuit arrangement as claimed in claim 1, wherein the evaluation circuit is set up for the evaluation of at least one sensor event of a sensor event detected by at least one of the sensor elements.

6. The circuit arrangement as claimed in claim 5, wherein the evaluation circuit includes at least one of the following electrical components:
at least one voltage source,
at least one current source,
at least one amplifier unit,
at least one switch unit, and
at least one charge storage device.

7. The circuit arrangement as claimed in claim 1, wherein the addressing unit is formed as at least one of a shift register, a latch and a memory element.

8. The circuit arrangement as claimed in claim 1, further comprising a counterelectrode for setting the electrical potential of an electrolyte that is to be applied to the circuit arrangement.

9. The circuit arrangement as claimed in claim 8, further comprising a reference electrode for detecting the electrolyte potential and for driving the counterelectrode in such a way that a constant electrolyte potential is provided.

10. The circuit arrangement as claimed in claim 1, wherein each sensor element comprises at least one of the following components:
at least one switch element,
a preamplifying unit, and
selection logic.

11. The circuit arrangement as claimed in claim 2, wherein the circuit arrangement is set up as a CMOS circuit arrangement.

12. The circuit arrangement as claimed in claim 2, wherein at least one of the sensor elements and the actuator elements are set up as at least one of biosensor elements and chemosensor elements.

13. The circuit arrangement as claimed in claim 2, wherein the evaluation circuit is set up for the evaluation of at least one sensor event of a sensor event detected by at least one of the sensor elements.

14. The circuit arrangement as claimed in claim 13, wherein the evaluation circuit includes at least one of the following electrical components:
at least one voltage source,
at least one current source,
at least one amplifier unit,
at least one switch unit, and
at least one charge storage device.

15. A circuit arrangement comprising:
a substrate,
at least one sensor array arranged at least one of on and in the substrate;
at least one operating circuit, integrated at least one of on and in the substrate, to drive the at least one sensor array, the sensor array being electrically coupled to the operating circuit region and the operating circuit and the sensor array being arranged in a manner spatially separate from one another.

16. The circuit arrangement as claimed in claim 15, wherein the operating circuit region is arranged around at least one of the sensor/actuator region and in the substrate.

17. The circuit arrangement as claimed in claim 15, wherein the circuit arrangement is set up as a CMOS circuit arrangement.

18. The circuit arrangement as claimed in claim 15, wherein at least one of the sensor elements and the actuator elements are set up as at least one of biosensor elements and chemosensor elements.

19. The circuit arrangement as claimed in claim 15, wherein the evaluation circuit is set up for the evaluation of at least one sensor event of a sensor event detected by at least one of the sensor elements.

20. The circuit arrangement as claimed in claim 19, wherein the evaluation circuit includes at least one of the following electrical components:
at least one voltage source,
at least one current source,
at least one amplifier unit,
at least one switch unit, and
at least one charge storage device.
